(19) United States
(12) Patent Application Publication
(10) Pub. No.: US 2015/0131425 A9
(43) Pub. Date: May 14, 2015

(54) OPTICAL OSCILLATION DEVICE AND RECORDING APPARATUS

(71) Applicants: Goro Fujita, Kanagawa (JP); Tsutomu Maruyama, Kanagawa (JP); Masaru Kuramoto, Kanagawa (JP); Hideki Watanabe, Kanagawa (JP)

(72) Inventors: Goro Fujita, Kanagawa (JP); Tsutomu Maruyama, Kanagawa (JP); Masaru Kuramoto, Kanagawa (JP); Hideki Watanabe, Kanagawa (JP)

(73) Assignee: SONY CORPORATION, Tokyo (JP)

(21) Appl. No.: 13/545,688

(22) Filed: Jul. 10, 2012

Related U.S. Application Data
(63) Continuation-in-part of application No. 13/540,858, filed on Jul. 3, 2012, now Pat. No. 8,462,599.

(30) Foreign Application Priority Data
Jul. 19, 2011 (JP) 2011-158321
Jul. 19, 2011 (JP) 2011-158323

(51) Int. Cl. G11B 7/126; G11B 7/1374; H01S 5/065; H01S 5/0625; H01S 5/026; G11B 7/1275; H01S 5/34; H01S 5/343

(52) U.S. Cl. CPC G11B 7/126; H01S 5/34333; H01S 5/0658; H01S 5/06253; H01S 5/0261; G11B 7/1275
USPC 369/112.05; 369/112.23; 372/45.01; G9B/7.121; 372/38.01

(57) ABSTRACT

Provided is a recording apparatus including a self-excited oscillation semiconductor laser that has a double quantum well separate confinement heterostructure and includes a saturable absorber section to which a negative bias voltage is applied and a gain section into which a gain current is injected, an optical separation unit, an objective lens, a light reception element, a pulse detection unit, a reference signal generation unit, a phase comparison unit, a recording signal generation unit, and a control unit.

### CROSS REFERENCES TO RELATED APPLICATIONS

The present application claims priority to Japanese Priority Patent Application JP 2011-158321 filed in the Japan Patent Office on Jul. 19, 2011, the entire content of which is hereby incorporated by reference.

### BACKGROUND

The present application relates to an optical oscillation device emitting laser light and a recording apparatus using the optical oscillation device.

In recent years, larger capacity and higher speed of communication have been necessary with the development of information application (IT) in society. Therefore, with regard to media used to propagate information, optical communication technologies of using not only radio waves with frequencies of, for example, a 2.4 GHz band and a 5 GHz band, as in radio communication, but also light with a wavelength of, for example, a 1.5 μm band (up to hundreds of THz in frequency) have rapidly come into wide use.

For example, a method of transmitting information by light is used not only for optical communication such as optical fiber communication but also for recording and reproducing information on and from recording media. Therefore, optical information technologies will become an important basis for supporting the development of the future information society.

When information is transmitted or recorded by light, a light source that oscillates specific pulses is necessary. In particular, high-output and short-pulse light sources are indispensable in communication and for large capacity and high speed of recorded and reproduced information, and thus various semiconductor lasers have been studied and developed as the light sources that satisfy the large capacity and high speed of the information.

For example, when reproduction from an optical disc is performed using a single-mode laser, noise may occur due to interference of an optical system and an oscillation wavelength may also be changed due to a change in temperature, and therefore output variation or noise may occur.

Accordingly, a high-frequency superimposing circuit performs a modulation process of changing the mode of a laser to a multi-mode from the outside to suppress an output variation caused due to a change in temperature or due to light returned from an optical disc. However, this method may lead to an increase in the size of an apparatus in proportion to addition of the high-frequency superimposing circuit, and thus may lead to an increase in cost.

In a self-excited oscillation semiconductor laser, however, the output variation can be suppressed even without using the high-frequency superimposing circuit, since multi-mode oscillation can be directly realized by blinking a light source at a high frequency.

For example, the proposers of the present application have realized a light source capable of achieving an oscillation output of 10 W and a pulse width of 15 psec at the frequency of 1 GHz using a self-excited oscillation GaN violet-blue semiconductor laser (for example, see Applied Physics Express 3, (2010) 052701 by Hideki Watanabe, Takao Miyajima, Masaru Kuramoto, Masao Ikeda, and Hiroyuki Yokoyama).

This semiconductor laser is a tri-sectional self-excited oscillation semiconductor laser that includes a saturable absorber section and two gain sections between which the saturable absorber section is interposed.

This semiconductor laser applies a reverse bias voltage to the saturable absorber section. At this time, laser light with a wavelength of, for example, 407 nm is emitted by injecting a current into the two gain sections.

### SUMMARY

The light source that achieves the high output and the short pulse width is expected to be applied to, for example, a recording light source for a two-photon absorption recording medium or various fields such as non-linear optical biological body imaging or micromachining.

In recent years, optical circuits in which silicon electronic devices are connected to one another by optical wiring and signal transmission is performed by light to realize high-speed signal transmission have been suggested. In the future, to enable the optical circuit to perform a calculating process, an optical oscillator that generates a mask clock of the electronic circuit is necessary.

When a self-excited oscillation type laser is used as the optical oscillator, a specific frequency should be prepared according to a use.

It is necessary for a recording and reproducing apparatus to output a Worb signal read from an optical recording medium or a recording signal synchronized with a rotation synchronization signal from a spindle motor that rotates an optical recording medium from a light source.

However, a specific pulsed light frequency may be generally determined as the frequency of the self-excited oscillation type laser depending on the configuration of the self-excited oscillation type laser. For this reason, it is necessary to manufacture the laser according to a use and it necessary to realize considerably high manufacturing accuracy. Therefore, the manufacturing cost may increase.

It is desirable to provide an optical oscillation device and a recording apparatus capable of easily obtaining a desired frequency of pulsed light with a simple configuration.

According to an embodiment of the present application, there is provided an optical oscillation device including a self-excited oscillation semiconductor laser that has a double quantum well separate confinement heterostructure and includes a saturable absorber section to which a negative bias voltage is applied and a gain section into which a gain current is injected.

The optical oscillation device according to the embodiment of the present application includes an optical separation unit that separates an oscillated light beam from the self-excited oscillation semiconductor laser into two oscillated light beams; a light reception element that receives one of the oscillated light beams separated by the optical separation unit; and a pulse detection unit that detects a pulse of the oscillated light beam received by the light reception element.

The optical oscillation device according to the embodiment of the present application includes a reference signal generation unit that generates a master clock signal; and a phase comparison unit that calculates a phase difference between the master clock signal and the pulse.

The optical oscillation device according to the embodiment of the present application includes a signal generation unit that generates a predetermined signal using a negative voltage at a timing of the master clock signal and applies the predetermined signal as the negative bias voltage to the saturable absorber unit of the self-excited oscillation semiconductor laser.

The optical oscillation device according to the embodiment of the present application includes a control unit that controls an oscillation frequency of the self-excited oscillation semiconductor laser by changing the gain current to be injected into the gain section of the self-excited oscillation semiconductor laser or the negative bias voltage to be applied to the saturable absorber unit based on the phase difference.

According to another embodiment of the present application, there is provided a recording apparatus including a recording signal generation unit that generates a recording signal instead of the above-described signal generation unit of the optical oscillation device and an objective lens that condenses one of the oscillated light beams separated by the above-described optical separation unit on the optical recording medium.

In the optical oscillation device and the recording apparatus according to the embodiments of the present application, the oscillation frequency of the oscillated light beam can be controlled by controlling one of the gain current to be injected into the gain section of the self-excited oscillation semiconductor laser and the negative bias voltage to be applied to the saturable absorber section.

Accordingly, the self-excited oscillation semiconductor laser can easily emit light at any oscillation frequency.

In the optical oscillation device and the recording apparatus according to the embodiments of the present application described above, the oscillated light beam of any oscillation frequency can be easily obtained.

Additional features and advantages are described herein, and will be apparent from the following Detailed Description and the figures.

### BRIEF DESCRIPTION OF THE FIGURES

FIG. 1 is a schematic diagram illustrating the configuration of a self-excited oscillation semiconductor laser;

FIG. 2 is a diagram illustrating a relation between a gain current injected into the self-excited oscillation semiconductor laser and an oscillation frequency of oscillated light beam emitted from the self-excited oscillation semiconductor laser;

FIG. 3 is a diagram illustrating a relation between a reverse bias voltage applied to the self-excited oscillation semiconductor laser and the oscillated frequency of the oscillated light beam emitted from the self-excited oscillation semiconductor laser;

FIG. 4 is a diagram illustrating a relation between the reverse bias voltage applied to the self-excited oscillation semiconductor laser and a peak power of the oscillated light beam emitted from the self-excited oscillation semiconductor laser;

FIG. 5 is a diagram illustrating a relation between the reverse bias voltage applied to the self-excited oscillation semiconductor laser and the peak power of the oscillated light beam emitted from the self-excited oscillation semiconductor laser;

FIG. 6 is a diagram illustrating a relation between the gain current injected into the self-excited oscillation semiconductor laser and the peak power of the oscillated light beam emitted from the self-excited oscillation semiconductor laser;

FIG. 7A is a diagram illustrating a relation among the gain current injected into the self-excited oscillation semiconductor laser, a charge density, and a light emission threshold value;

FIG. 7B is a diagram illustrating a waveform of pulsed light emitted from the self-excited oscillation semiconductor laser;

FIG. 8A is a diagram illustrating a binary signal;

FIG. 8B is a diagram illustrating a relation among the gain current injected into the self-excited oscillation semiconductor laser, a charge density, and a light emission threshold value;

FIG. 8C is a diagram illustrating a waveform of pulsed light emitted from the self-excited oscillation semiconductor laser;

FIG. 9A is a diagram illustrating a waveform of oscillated light beam emitted from the self-excited oscillation semiconductor laser;

FIG. 9B is a diagram illustrating a reverse bias voltage applied to the self-excited oscillation semiconductor laser;

FIG. 10A is a diagram illustrating a waveform of oscillated light beam emitted from the self-excited oscillation semiconductor laser;

FIG. 10B is a diagram illustrating a reverse bias voltage applied to the self-excited oscillation semiconductor laser;

FIG. 11 is a schematic diagram illustrating the configuration of a recording apparatus according to a first embodiment; and

FIG. 12 is a schematic diagram illustrating the configuration of a recording apparatus according to a second embodiment.

### DETAILED DESCRIPTION

Hereinafter, preferred embodiments of the present application will be described, but the present application is not limited to the embodiments. The description will be made in the following order:

1. Configuration of Self-excited Oscillation Semiconductor Laser,

2. First Embodiment (Control Example of Oscillation Frequency by Direct Current During Oscillation Period), and

3. Second Embodiment (Control Example of Oscillation Frequency of Direct Current Voltage During Oscillation Period).

### 1. Configuration of Self-excited Oscillation Semiconductor Laser

First, the configuration of a self-excited oscillation semiconductor laser 1 according to an embodiment of the present application will be described.

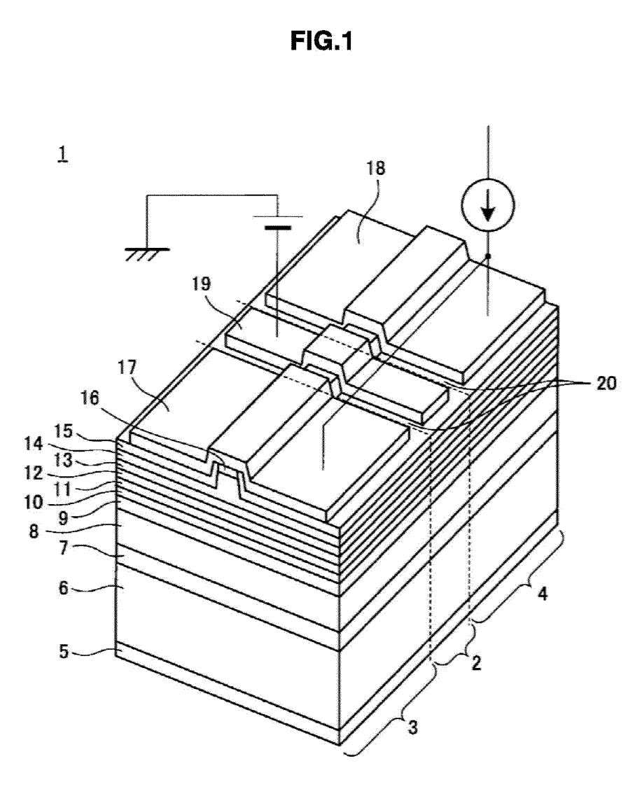

FIG. 1 is a schematic diagram illustrating the configuration of the self-excited oscillation semiconductor laser 1 according to the embodiment of the present application. The self-excited oscillation semiconductor laser 1 is a self-excited oscillation semiconductor laser disclosed in Applied Physics Express 3, (2010) 052701 by Hideki Watanabe, Takao Miyajima, Masaru Kuramoto, Masao Ikeda, and Hiroyuki Yokoyama.

The self-excited oscillation semiconductor laser 1 is a tri-sectional type self-excited oscillation semiconductor laser that includes a saturable absorber section 2, a first gain section 3, and a second gain section 4.

As shown in FIG. 1, the saturable absorber section 2 is interposed between the first gain section 3 and the second gain section 4.

When the saturable absorber section 2 is provided, the absorptance of an absorber decreases with an increase in the intensity of light incident on the absorber. Therefore, since only a pulse with a high intensity penetrates the absorber, a narrower pulse can be obtained.

Further, a gain current is injected into the first gain section 3 and the second gain section 4.

A double quantum well separate confinement heterostructure formed of GaInN/GaN/AlGaN materials is formed on a (0001) surface of an n-type GaN substrate 6.

That is, an n-type GaN layer 7, an n-type AlGaN clad layer 8, an n-type GaN guide layer 9, and a double quantum well active layer 10 are sequentially laminated on one surface of the n-type GaN substrate 6. Further, a GaInN guide layer 11, a p-type AlGaN layer 12, a p-type AlGaN barrier layer 13, and a p-type AlGaN/GaN superlattice first-clad layer 14 are sequentially laminated on the double quantum well active layer 10.

The double quantum well separate confinement heterostructure may be formed by, for example, a metal organic chemical vapor deposition (MOCVD) method.

As shown in FIG. 1, a ridge structure is formed in the central portion of the p-type AlGaN/GaN superlattice first-clad layer 14, and a p-type GaN contact layer 16 is formed on the upper surface of the ridge structure. Further, a SiO₂/Si insulating layer 15 is formed on the side surface of the ridge structure or a portion of the p-type AlGaN/GaN superlattice first-clad layer 14 in which the ridge structure is not formed.

A first main electrode 17, a second main electrode 18, and a sub-electrode 19, which are p-type electrodes, are formed on the p-type GaN contact layer 16 and the SiO₂/Si insulating layer 15 by ohmic contact.

Specifically, the first main electrode 17 is formed on the first gain section 3 and the sub-electrode 19 is formed on the saturable absorber section 2. Further, the second main electrode 18 is formed on the second gain section 4. These electrodes are electrically isolated from each other by groove-shaped isolation portions 20.

An n-type lower electrode 5 is formed on a surface of the n-type GaN substrate 6 opposite to the n-type GaN layer 7 by ohmic contact.

In the self-excited oscillation semiconductor laser 1, as shown in FIG. 1, the sub-electrode 19 applies a reverse bias voltage to the saturable absorber section 2. At this time, when a current (gain current) is injected into the first gain section 3 and the second gain section 4 from the first main electrode 17 and the second main electrode 18, respectively, laser light is emitted.

The proposers of the present application have found that oscillated light beam may be modulated by changing the above-described reverse bias voltage and an oscillation frequency may be controlled by changing the above-described gain current (direct current) in the self-excited oscillation semiconductor laser 1.

Further, the proposers of the present application have found that oscillated light beam may be modulated by changing the reverse bias voltage and an oscillation frequency may be controlled by changing the value of the reverse bias voltage (a current voltage during an oscillation period) during an oscillation period of the self-excited oscillation semiconductor laser 1. Here, the reverse bias voltage during the oscillation period is a direct current voltage with a constant voltage value during the oscillation period.

That is, in the embodiment of the present application, the modulation of the oscillation light is performed by controlling the reverse bias voltage and the control of the oscillation frequency is performed by controlling the reverse bias voltage during the oscillation period or the value of the direct-current signal by the gain current.

Here, in the embodiment of the present application, the direct-current signal during the oscillation period means that the reverse bias voltage is a direct current voltage during the oscillation of the self-excited oscillation semiconductor laser 1 and the gain current is a direct current. In addition, the oscillation frequency may be controlled by controlling the value of one of the reverse bias voltage and the gain current.

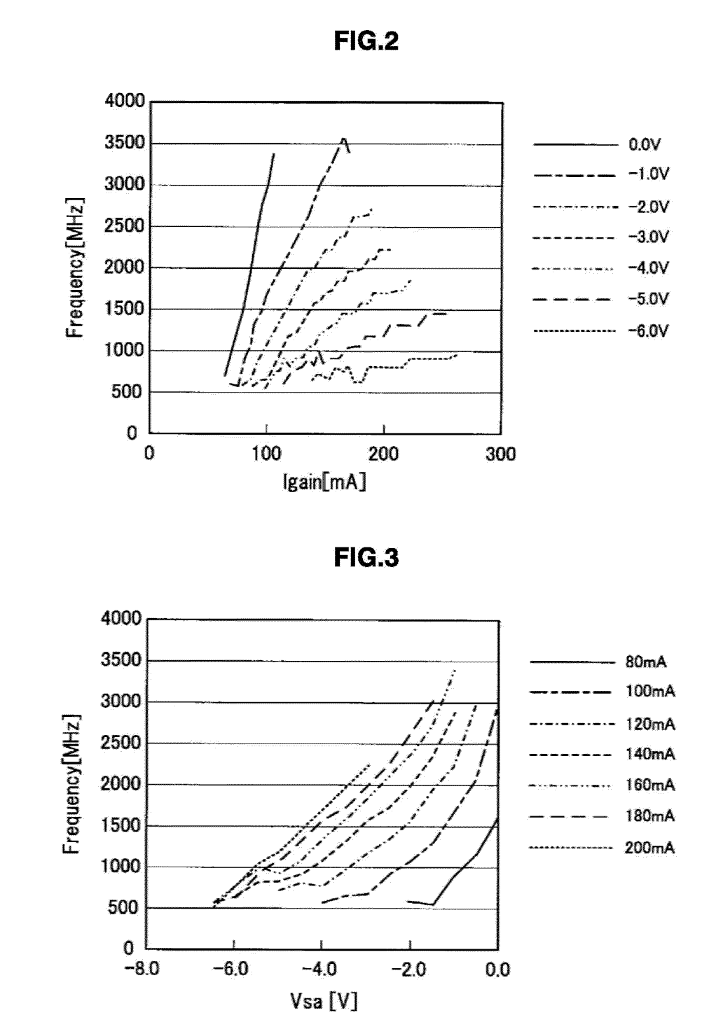

For example, FIG. 2 shows a measurement result of the oscillation frequency of the oscillated light beam when the reverse bias voltage (direct current voltage) at the oscillation time is made to be constant and the gain current is changed in the self-excited oscillation semiconductor laser 1 according to the embodiment of the present application. The horizontal axis represents a gain current (Igain) and the vertical axis represents an oscillation frequency. A change in the oscillation frequency at each voltage value is examined, while changing the reverse bias voltage (Vsa) at intervals of 1.0 V from 0 V to −6.0 V.

As shown in FIG. 2, it can be understood that the oscillation frequency of the oscillated light beam emitted from the self-excited oscillation semiconductor laser 1 increases when the reverse bias voltage (Vsa) is constant and the gain current (Igain) increases. Accordingly, the oscillation frequency may be controlled by changing the value of the gain current (direct current) in the oscillation of the self-excited oscillation semiconductor laser 1.

In FIG. 3, on the other hand, a change in the oscillation frequency is examined with respect to the change in the reverse bias voltage (direct current voltage in the oscillation) in the oscillation of the self-excited oscillation semiconductor laser 1 when the gain current (direct current) is constant. The horizontal axis represents the reverse bias voltage (Vsa) and the vertical axis represents the oscillation frequency. Further, the change in the oscillation frequency at each current value is examined while changing the gain current at intervals of 20 mA from 80 mA to 200 mA.

As shown in FIG. 3, it can be understood that the oscillation frequency of the oscillated light beam emitted from the self-excited oscillation semiconductor laser 1 decreases when the gain current (Igain) is constant and the reverse bias voltage (Vsa) increases in the negative direction. That is, the oscillation frequency may be controlled by changing the value of the reverse bias voltage (direct current voltage) in the oscillation (during the oscillation period) of the self-excited oscillation semiconductor laser 1.

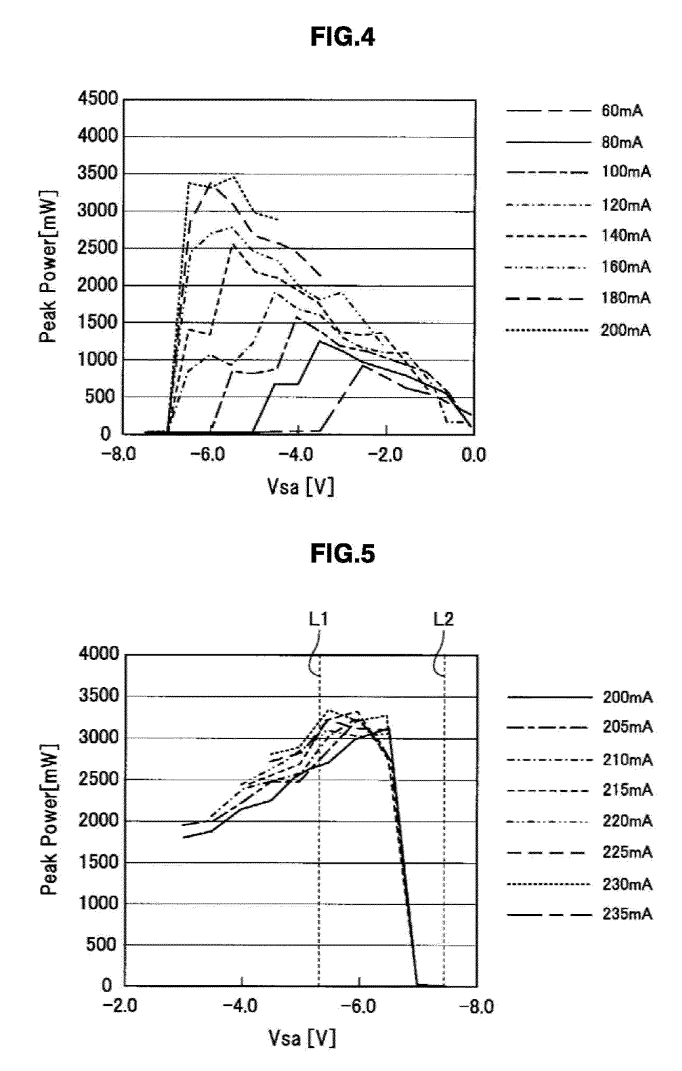

FIG. 4 is a diagram illustrating a relation between the reverse bias voltage (Vsa) applied to the self-excited oscillation semiconductor laser 1 and a peak power of the oscillated light beam emitted from the self-excited oscillation semiconductor laser 1 when the gain current (Igain) is constant at 200 mA or less. The horizontal axis represents the reverse bias voltage (Vsa) and the vertical axis represents the peak power.

As understood from FIG. 4, the peak power increases when the reverse bias voltage (Vsa) increases in the negative direction from zero. Further, when the reverse bias voltage becomes greater than a predetermined voltage in the negative direction, the peak power decreases and the oscillation finally stops.

Thus, since the value of the peak power is changed by the reverse bias voltage (Vsa), the peak power may be controlled using the reverse bias voltage (Vsa).

FIG. 5 is a diagram illustrating a relation between the reverse bias voltage (Vsa) applied to the self-excited oscillation semiconductor laser 1 and a peak power of the oscillated light beam emitted from the self-excited oscillation semiconductor laser 1 when the gain current (Igain) is constant at 200 mA or more. The horizontal axis represents the reverse bias voltage (Vsa) and the vertical axis represents the peak power. The change in the peak power at each current value is examined while changing the gain current at intervals of 5 mA from 200 mA to 235 mA.

As shown in FIG. 5, the oscillation of the self-excited oscillation semiconductor laser 1 stops when the reverse bias voltage (Vsa) increases in the negative direction from about −7 V in the range of the gain current (Igain). Accordingly, for example, the self-excited oscillation semiconductor laser 1 is in an ON (oscillation) state when the reverse bias voltage indicated by a line L1 of FIG. 5 is −5.5 V. The self-excited oscillation semiconductor laser 1 is in an OFF (non-oscillation) state when the reverse bias voltage indicated by a line L2 is −7.5 V. That is, for example, the ON (oscillation) state and the OFF (non-oscillation) state of the self-excited oscillation semiconductor laser 1 may be controlled by switching the reverse bias voltage to −5.5 V and −7.5 V.

Thus, the oscillated light beam emitted from the self-excited oscillation semiconductor laser 1 may be modulated by controlling the reverse bias voltage.

The values of the peak power shown in FIGS. 4 and 5 are calculated based on an average power monitored-value of the light output and the pulse width measured by a high-speed photo detector (40 GHz). Since only about 40 ps is detected with respect to the actual minimum pulse width of 15 ps because of the shortage of the bandwidth of the photo detector, a low peak value is displayed.

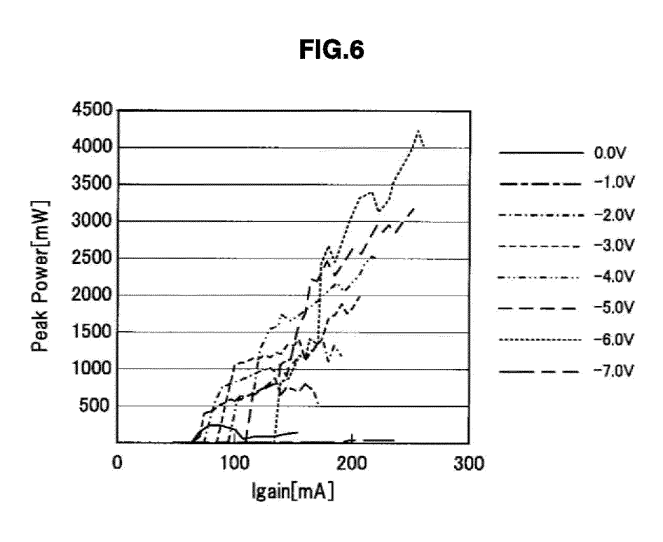

FIG. 6 is a diagram illustrating a relation between the gain current (Igain) injected into the self-excited oscillation semiconductor laser 1 and the peak power of the oscillated light beam emitted from the self-excited oscillation semiconductor laser 1 when the reverse bias voltage (Vsa) is constant. The horizontal axis represents the gain current and the vertical axis represents the peak power.

As understood from FIG. 6, the greater the gain current (Igain) is, the greater the peak power of the oscillated light beam is. Accordingly, the peak power of the oscillated light beam from the self-excited oscillation semiconductor laser 1 may be controlled by the gain current (Igain).

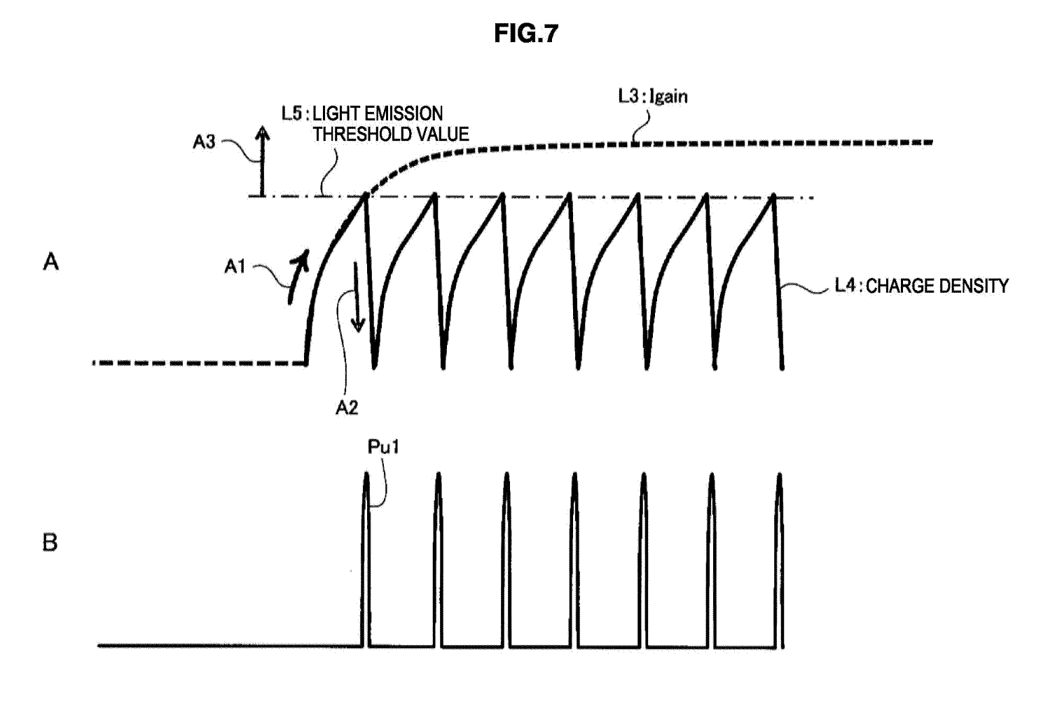

The above-described characteristics of the self-excited oscillation semiconductor laser 1 will be described below with reference to FIGS. 7A and 7B.

FIG. 7A is a diagram illustrating a relation between the gain current injected into the self-excited oscillation semiconductor laser 1 and the density of charge accumulated in the self-excited oscillation semiconductor laser 1 by current injection. FIG. 7B is a diagram illustrating a waveform of light emitted from the self-excited oscillation semiconductor laser 1 when the current is injected. Further, the reverse bias voltage is set to have a constant value.

In FIG. 7A, a characteristic L3 is a current injected into the self-excited oscillation semiconductor laser 1 and a characteristic L4 is the density of the charge (hereinafter referred to as a charge density) accumulated in the self-excited oscillation semiconductor laser 1, when the current is injected.

As indicated by an arrow A1, the larger the gain current is, the higher the charge density of the charge accumulated in the self-excited oscillation semiconductor laser 1 is. When the charge density reaches a light emission threshold value indicated by a characteristic L5, pulsed light Pu1 shown in FIG. 7B is emitted. At this time, the charge is consumed when the pulsed light is emitted. Thus, the charge density in the self-excited oscillation semiconductor laser 1 is lowered, as indicated by an arrow A2.

Then, the charge is accumulated again in the self-excited oscillation semiconductor laser 1 by the gain current. When the charge density reaches the light emission threshold value indicated by the characteristic L5, the pulsed light is emitted. The self-excited oscillation semiconductor laser 1 performs continuous oscillation of the pulsed light by repeating the course.

The light emission threshold value, which is indicated by the characteristic L5, for the charge density is changed by the value of the reverse bias voltage applied to the self-excited oscillation semiconductor laser 1.

For example, when the reverse bias voltage increases in the negative direction, the light emission threshold value, which is indicated by the characteristic L5, for the charge density increases, as indicated by an arrow A3. Therefore, since a time in which the charge density reaches the light emission threshold value becomes longer, the emission interval of the pulsed light becomes longer and the oscillation frequency of the self-excited oscillation semiconductor laser 1 thus decreases.

That is, according to this principle, the oscillation frequency of the self-excited oscillation semiconductor laser 1 may be controlled using the reverse bias voltage.

Further, when the light emission threshold value increases by increasing the reverse bias voltage in the negative direction, the charge density necessary for the oscillation of the laser light also increases. Therefore, since the amount of charge consumed in the oscillation increases, the energy of the emitted pulsed light also increases. Thus, the peak power of the oscillated light beam from the self-excited oscillation semiconductor laser 1 may be controlled using the reverse bias voltage.

When the value of the gain current increases, a time in which the charge density reaches the light emission threshold value indicated by the characteristic L5 is shortened. Therefore, since the emission interval of the pulsed light is shorter, the oscillation frequency of the self-excited oscillation semiconductor laser 1 increases.

That is, according to this principle, the oscillation frequency of the self-excited oscillation semiconductor laser 1 may be controlled using the gain current.

On the other hand, the charge accumulated in the self-excited oscillation semiconductor laser 1 does not flow out (is not consumed) spontaneously from the self-excited oscillation semiconductor laser 1 except for the consumption of the pulsed light when the pulsed light is emitted. Therefore, there is a limit to the amount of charge (charge density) which can be accumulated in the self-excited oscillation semiconductor laser 1.

Therefore, when the value of the reverse bias voltage Vsa excessively increases in the negative direction, the light emission threshold value for the charge density which can be accumulated considerably increases. Thus, it is difficult to increase the charge density up to the light emission threshold value. For this reason, as shown in FIG. 4, when the reverse bias voltage Vsa increases up to a predetermined value in the negative direction, the self-excited oscillation semiconductor laser 1 does not oscillate.

In the reverse bias voltage Vsa, a threshold value at which the self-excited oscillation semiconductor laser 1 does not oscillate is present in the region of the negative value. Accordingly, to switch between the ON and OFF sates of the self-excited oscillation semiconductor laser 1, the reverse bias voltage in the OFF state is preferably set to a value greater than the threshold value in the negative direction. In other words, in the self-excited oscillation semiconductor laser 1 in which the reverse bias voltage is set to the value greater than the threshold value in the negative direction, the bias voltage during the non-oscillation period in which the oscillation of the laser light stops becomes greater than the reverse bias voltage in the negative direction during the oscillation period in which the laser light oscillates.

By setting the reverse bias voltage in this way, the ON and OFF states of the self-excited oscillation semiconductor laser 1 can be switched.

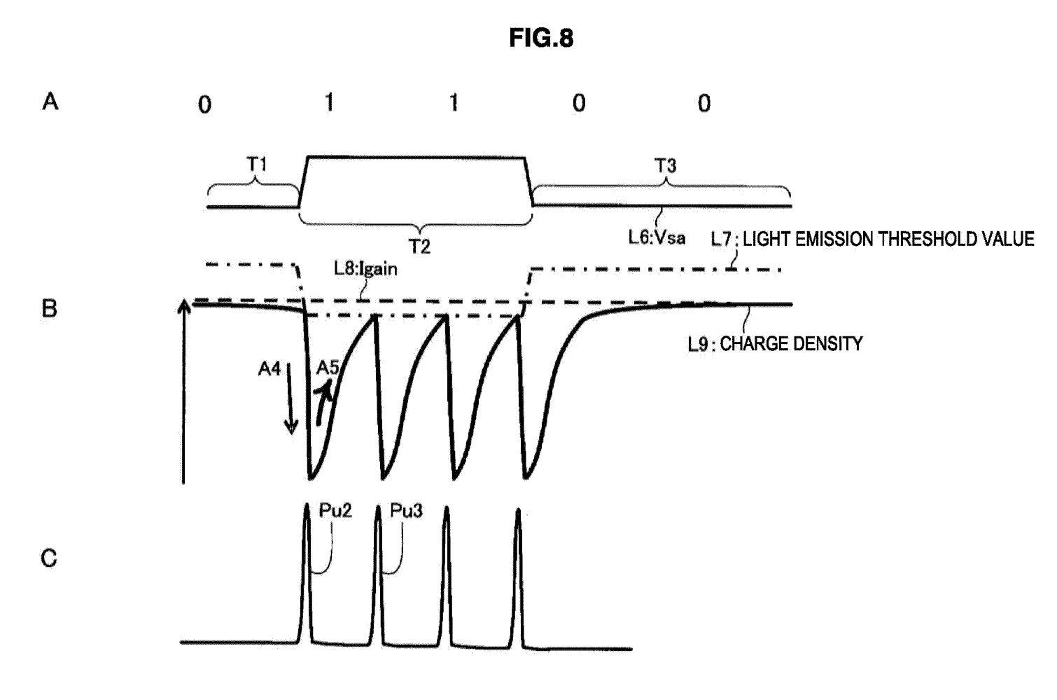

A principle of the modulation of the oscillated light beam emitted from the self-excited oscillation semiconductor laser 1 by the control of the reverse bias voltage will be described below with reference to FIGS. 8A to 8C.

As shown in FIG. 8A, for example, a binary signal is considered in which 0, 1, 1, 0, and 0 are sequentially set in the oscillated light beam of the self-excited oscillation semiconductor laser 1. FIG. 8B is a diagram illustrating a waveform (characteristic L6) of the reverse bias voltage applied to the self-excited oscillation semiconductor laser 1, a light emission threshold value (characteristic L7) at this time, the waveform (characteristic L8) of the gain current injected into the self-excited oscillation semiconductor laser 1, and a charge density (characteristic L9) of the charge accumulated in the self-excited oscillation semiconductor laser 1. FIG. 8C is a diagram illustrating a waveform of the oscillated light beam emitted from the self-excited oscillation semiconductor laser 1 at this time.

As shown in FIG. 8C, it is assumed that two beams of the pulsed light emitted from the self-excited oscillation semiconductor laser 1 correspond to ‘1’ of the binary signal.

First, when ‘0’ of the binary signal is expressed by the self-excited oscillation semiconductor laser 1, the charge density indicated by the characteristic L9 does not exceed the light emission threshold value indicated by the characteristic L7 during a period T1 shown in FIG. 8B. Accordingly, the self-excited oscillation semiconductor laser 1 does not oscillate during the period T1 (non-oscillation period).

On the other hand, when ‘1’ of the binary signal is expressed by the self-excited oscillation semiconductor laser 1, the reverse bias voltage indicated by the characteristic L6 increases in the positive direction within the range of the negative value during the period T2 shown in FIG. 8B. Thus, the light emission threshold value indicated by the characteristic L7 decreases, and thus the charge density indicated by the characteristic L9 reaches the light emission threshold value. As a result, pulsed light Pu2 shown in FIG. 8C is emitted.

When the pulsed light Pu2 is emitted and the charge is thus consumed, as indicated by an arrow A4 of FIG. 8B, the charge density is lowered. On the other hand, since the gain current indicated by the characteristic L8 is a direct current with a constant value during the period T1 (non-oscillation period) and during the period T2 (oscillation period), the charge can be accumulated again in the self-excited oscillation semiconductor laser 1. Therefore, as indicated by an arrow A5, the charge density increases. At this time, since the reverse bias voltage indicated by the characteristic L6 is a direct current voltage with a constant value during the period T2, the light emission threshold value indicated by the characteristic L7 remains low. Accordingly, the charge density reaches the light emission threshold value again. Thus, pulsed light Pu3 shown in FIG. 8C is emitted and ‘1’ of the binary signal is expressed.

When ‘1’ of the binary signal is switched to ‘0,’ the reverse bias voltage indicated by the characteristic L6 increases in the negative direction, as shown in a period T3 (non-oscillation period) of FIG. 8B. Thus, during the period T3, the light emission threshold value indicated by the characteristic L7 increases and the charge density indicated by the characteristic L9 does not reach the light emission threshold value. Accordingly, the self-excited oscillation semiconductor laser 1 does not oscillate and enters a stop state, and ‘0’ of the binary signal is expressed.

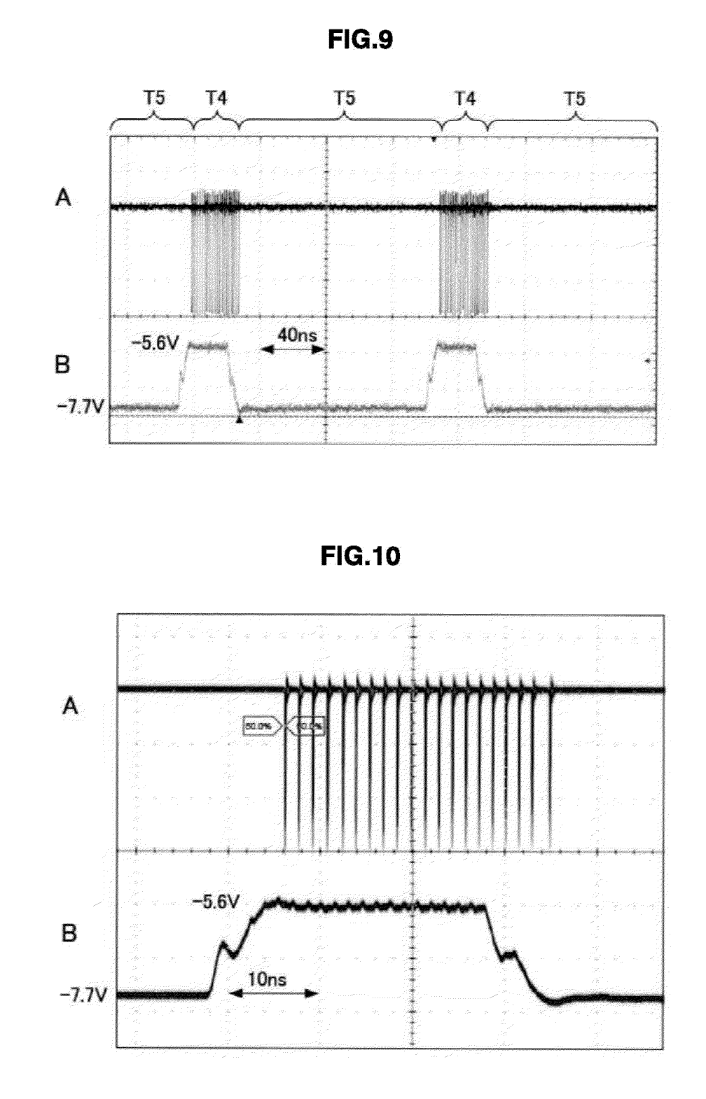

A verification experiment result of the modulation process is shown in FIGS. 9A and 9B. FIG. 9A is a diagram illustrating the waveform of the oscillated light beam emitted from the self-excited oscillation semiconductor laser 1. FIG. 9B is a diagram illustrating the reverse bias voltage applied to the self-excited oscillation semiconductor laser 1.

The reverse bias voltage is set to −5.6 V during an oscillation period (30 nsec) shown in a period T4 and is set to −7.7 V during a non-oscillation period (120 nsec) shown in a period T5. The gain current is set to 230 mA, which is constant during the period T4 and the period T5.

As understood from FIGS. 9A and 9B, the self-excited oscillation semiconductor laser 1 does not oscillate during the period T5 in which the reverse bias voltage is −7.7 V. On the other hand, the self-excited oscillation semiconductor laser 1 continuously oscillates a plurality of pulsed light during the period T4 in which the reverse bias voltage is −5.6 V, and thus an oscillation output of 7.9 W can be obtained.

Thus, it can be known that the ON state (oscillation period) and the OFF state (non-oscillation period) of the self-excited oscillation semiconductor laser 1 may be switched by switching the reverse bias voltage to −5.6 V and −7.7 V. That is, the oscillated light beam emitted from the self-excited oscillation semiconductor laser 1 may be modulated by controlling the reverse bias voltage.

FIGS. 10A and 10B are expanded diagrams illustrating the waveform of the oscillated light beam emitted from the self-excited oscillation semiconductor laser 1 and the waveform of the reverse bias voltage, respectively, during the period T4 (oscillation period). Further, the waveform indicates the afterimages of a plurality of light emission waveforms repeated through synchronization for which the voltage of the reverse bias voltage serves as a trigger, and thus indicates the synchronization property.

As shown in FIG. 10, it can be understood that the oscillation of the self-excited oscillation semiconductor laser 1 starts within 10 nsec after the reverse bias voltage increases from −7.7 V to −5.6 V. Accordingly, it can be said that the self-excited oscillation semiconductor laser 1 emits the oscillated light beam satisfactorily synchronized with a modulation signal applied as the reverse bias voltage to the self-excited oscillation semiconductor laser 1.

### 2. First Embodiment (Control Example of Oscillation Frequency by Direct Current During Oscillation Period)

A recording apparatus including the self-excited oscillation semiconductor laser 1 having the above-described characteristics will be described below.

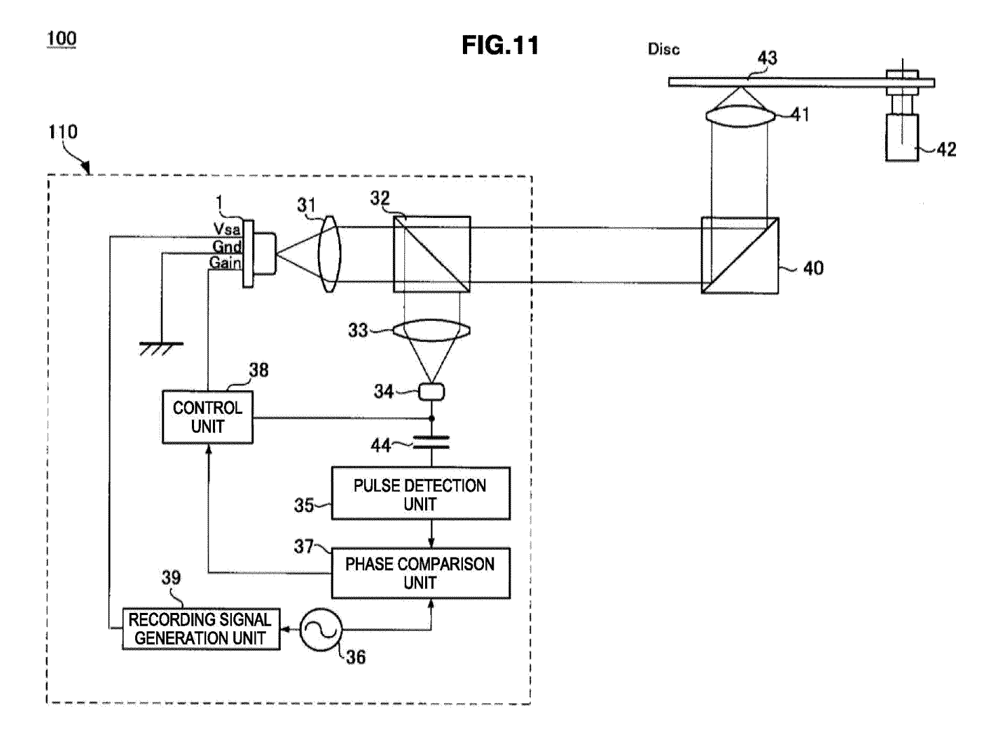

FIG. 11 is a schematic diagram illustrating the configuration of a recording apparatus 100 according to a first embodiment. The recording apparatus 100 according to this embodiment includes an optical oscillation unit 110 and an objective lens 41 that condenses the oscillated light beam emitted from the optical oscillation unit 110 on an optical recording medium 43.

The recording apparatus 100 according to this embodiment includes a mirror 40 that guides the oscillated light beam emitted from the optical oscillation unit 110 toward the objective lens 41 and a spindle motor 42 that rotates an optical recording medium 43 in an in-plane direction of the optical recording medium 43.

The optical oscillation unit 110 includes the above-described self-excited oscillation semiconductor laser 1 serving as a light source, a collimator lens 31 that collimates the light from the self-excited oscillation semiconductor laser 1, and a optical separation unit 32 that separates the light having passed through the collimator lens 31 into beams.

The optical oscillation unit 110 further includes a collecting lens 33 that collects one beam of the light separated by the optical separation unit 32 and a light reception element 34 that receives the light collected by the collecting lens 33.

The optical oscillation unit 110 further includes a pulse detection unit 35 that detects the light received by the light reception unit 34, a reference signal generation unit 36 that generates a master clock signal, and a phase comparison unit 37 that compares the phase of the light detected by the pulse detection unit 35 with the phase of the master clock signal.

The optical oscillation unit 110 according to this embodiment further includes a control unit 38 that controls the gain current to be injected into the self-excited oscillation semiconductor laser 1 based on a phase difference calculated by the phase comparison unit 37 and the intensity of the light received by the light reception element 34.

The optical oscillation unit 110 according to this embodiment further includes a recording signal generation unit 39 that generates a recording signal at a timing of the master clock signal.

First, the recording signal generation unit 39 generates a recording signal (binary signal) to be recorded in an optical recording medium such as an optical disc at the timing of the master clock signal generated by the reference signal generation unit 36. The recording signal is applied as the reverse bias voltage to the self-excited oscillation semiconductor laser 1.

In this case, as described above, the reverse bias voltage during the non-oscillation period (‘0’ of the binary signal) of the self-excited oscillation semiconductor laser 1 is set to a value greater than the reverse bias voltage during the oscillation period (‘1’ of the binary signal) in the negative direction. Thus, the oscillated light beam emitted from the self-excited oscillation semiconductor laser 1 may be modulated in accordance with the recording signal (see FIGS. 8A to 8C).

The oscillated light beam from the self-excited oscillation semiconductor laser 1 modulated in accordance with the recording signal is collimated by the collimator lens 31, and then is incident on the optical separation unit 32.

The optical separation unit 32, which is configured by, for example, a beam splitter, separates the light emitted from the self-excited oscillation semiconductor laser 1 into two light fluxes. Of the two separated light fluxes, for example, the light flux reflected from the optical separation unit 32 is collected on the light reception element 34 by the collecting lens 33. For example, a photodiode is used in the light reception element 34.

The pulse detection unit 35 is connected to the light reception element 34 via a capacitor 44 and detects the pulse of the light received by the light reception element 34.

The phase comparison unit 37 compares the phase of the master clock signal generated by the reference signal generation unit 36 with the phase of the pulse detected by the pulse detection unit 35 to calculate a phase difference between the phase of the master clock signal and the phase of the pulse.

The control unit 38 controls the frequency of the pulsed light oscillated from the self-excited oscillation semiconductor laser 1 by controlling the magnitude of the gain current to be injected into the self-excited oscillation semiconductor laser 1 based on the phase difference calculated by the phase comparison unit 37.

The control unit 38 also controls the gain current to be injected into the self-excited oscillation semiconductor laser 1 based on the intensity of the light received by the light reception element 34. That is, in this embodiment, the control of the frequency of the oscillated light beam and the control of the power of the oscillated light beam emitted from the self-excited oscillation semiconductor laser 1 may be performed by controlling the value of the gain current (the direct current constant during the oscillation period and during the non-oscillation period).

On the other hand, the oscillated light beam which has been emitted from the self-excited oscillation semiconductor laser 1 and has passed through the optical separation unit 32 is incident on the mirror 40. Then, the oscillated light beam is reflected from the mirror 40, the optical path of the oscillated light beam is thus changed, and then the oscillated light beam is incident on the objective lens 41.

The oscillated light beam incident on the objective lens 41 is collected on the optical recording medium 43. The optical recording medium 43 is rotated in the in-plane direction of an optical recording surface by a spindle motor 42. A collection spot of the laser light is frequently moved in a radial direction of the optical recording medium 43 by a thread motor (not shown) or the like. Accordingly, the oscillated light beam from the self-excited oscillation semiconductor laser 1 is emitted to the optical recording surface of the optical recording medium 43 in a spiral shape or a concentric shape, and thus recording information loaded on the oscillated light beam is sequentially recorded on the optical recording medium 43.

Thus, in the recording apparatus 100 according to this embodiment, the oscillated light beam emitted from the self-excited oscillation semiconductor laser 1 is modulated using the reverse bias voltage to be applied to the self-excited oscillation semiconductor laser 1. Since the reverse bias voltage is applied to the self-excited oscillation semiconductor laser 1 in accordance with the recording signal, the recording information can be loaded on the oscillated light beam emitted from the self-excited oscillation semiconductor laser 1.

In the recording apparatus 100 according this embodiment, the frequency and the output power of the oscillated light beam may be controlled using the gain current to be injected into the self-excited oscillation semiconductor laser 1. Thus, the frequency of the oscillated light beam can be appropriately set and the output power can be maintained to be constant normally. Accordingly, information can be recorded on an optical recording medium with good accuracy.

The power of the oscillated light beam emitted from the self-excited oscillation semiconductor laser 1 may be controlled by changing the value of the reverse bias voltage to be applied to the self-excited oscillation semiconductor laser 1 (see FIG. 4). Accordingly, the power of the oscillated light beam may be controlled by changing the value of the reverse bias voltage (the direct current voltage within the oscillation period) during the oscillation period, as long as the reverse bias voltage is within a possible modulation range of the oscillated light beam emitted from the self-excited oscillation semiconductor laser 1.

In this case, the control unit 38 may control the value of the reverse bias voltage (the direct current voltage within the oscillation period) during the oscillation period based on the intensity of the light received by the light reception element 34.

The signal loaded on the oscillated light beam from the self-excited oscillation semiconductor laser 1 is not limited to the recording signal, but may be any signal. That is, by providing a signal generation unit generating any given signal instead of the recording signal generation unit 39, the optical oscillation unit 110 may be configured as an optical oscillation device that emits the oscillated light beam on which the any given signal is loaded.

Here, the tri-sectional type self-excited oscillation semiconductor laser including two gain sections has been used as the self-excited oscillation semiconductor laser 1. However, the same operations and advantages can be obtained even when a bi-sectional type self-excited oscillation semiconductor laser including one gain section is used.

### 3. Second Embodiment (Control Example of Oscillation Frequency of Direct Current Voltage During Oscillation Period)

In the first embodiment, the oscillation frequency of the self-excited oscillation semiconductor laser 1 was controlled using the value of the gain current during the oscillation period. However, as shown in FIG. 3, the oscillation frequency of the self-excited oscillation semiconductor laser 1 is also changed using the value of the reverse bias voltage. Hereinafter, an example of a recording apparatus that controls the oscillation frequency of the self-excited oscillation semiconductor laser 1 using a reverse bias voltage will be described.

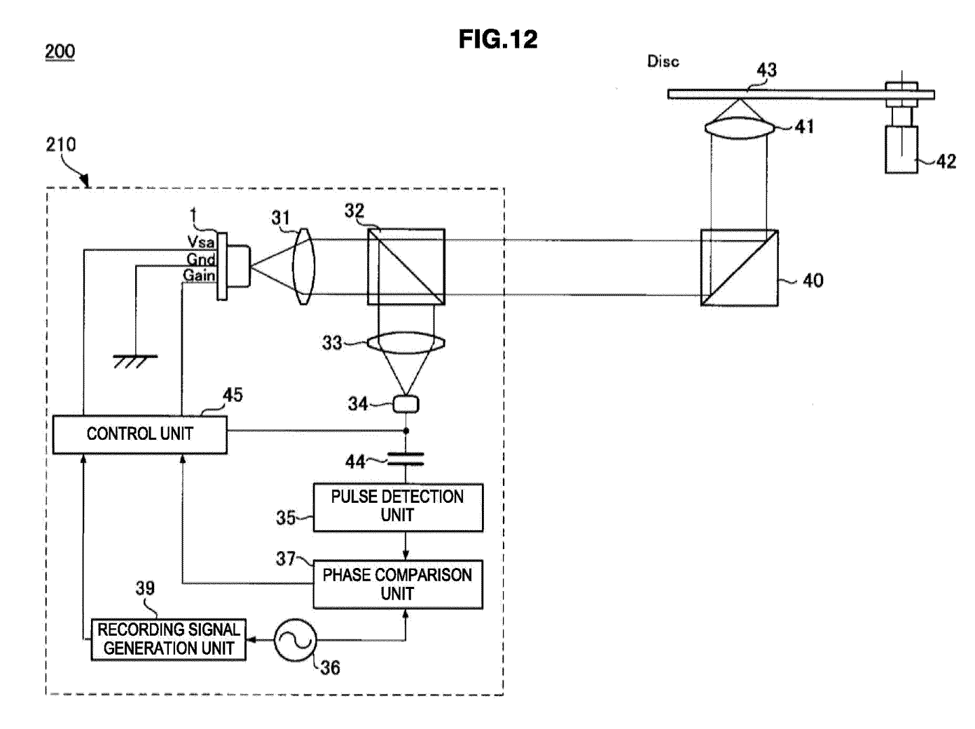

FIG. 12 is a schematic diagram illustrating the configuration of a recording apparatus 200 according to a second embodiment. The same reference numerals are given to units corresponding to the units of the first embodiment (see FIG. 11), and the description thereof will not be repeated.

The recording apparatus 200 according to this embodiment includes an optical oscillation unit 210 and an objective lens 41 that condenses the oscillated light beam emitted from the optical oscillation unit 210 on an optical recording medium 43.

The recording apparatus 200 according to this embodiment includes a mirror 40 that guides the oscillated light beam emitted from the optical oscillation unit 210 toward the objective lens 41 and a spindle motor 42 that rotates an optical recording medium 43 in an in-plane direction of the optical recording medium 43.

The recording apparatus 200 according to this embodiment is the same as the recording apparatus 100 according to the first embodiment except that the process of a control unit 45 of the optical oscillation unit 210 is different from the process of the control unit 38 of the first embodiment (see FIG. 11).

First, the control unit 45 controls the gain current (the direct current with a constant value during an oscillation period and during a non-oscillation period) to be injected into the self-excited oscillation semiconductor laser 1 based on the intensity of the light received by the light reception element 34 in the self-excited oscillation semiconductor laser 1. Thus, the power of the oscillated light beam emitted from the self-excited oscillation semiconductor laser 1 may be controlled.

The recording signal generated using a negative voltage at the timing of the master clock signal from the reference signal generation unit 36 by the recording signal generation unit 39 is applied as the reverse bias voltage to the saturable absorber section of the self-excited oscillation semiconductor laser 1.

At this time, for example, the reverse bias voltage corresponding to ‘0’ of the recording signal (binary signal) is greater than the reverse bias voltage corresponding to ‘1’ of the recording signal in the negative direction.

Accordingly, when ‘1’ of the recording signal is expressed, as in the first embodiment, the self-excited oscillation semiconductor laser 1 emits the oscillated light beam (oscillation period). When ‘0’ of the recording signal (binary signal) is expressed, the self-excited oscillation semiconductor laser 1 does not emit the oscillated signal (non-oscillation period). Thus, the oscillated light beam corresponding to the recording signal may be emitted from the self-excited oscillation semiconductor laser 1 by modulating the oscillated light beam emitted from the self-excited oscillation semiconductor laser 1.

This process is the same as that of the first embodiment. In this embodiment, however, the control unit 45 controls the value of the reverse bias voltage (recording signal) to be applied to the self-excited oscillation semiconductor laser 1 during an oscillation period (a period of ‘1’ of the binary signal).

The light emission threshold value during the oscillation period is changed by controlling the value of the reverse bias voltage (direct current voltage) during the oscillation period (see FIGS. 8A to 8C). At this time, the light emission threshold value is changed within a range in which there is no influence on the ON state (oscillation) and the OFF state (non-oscillation) of the self-excited oscillation semiconductor laser 1. As described above, since the oscillation frequency is changed with the change in the light emission threshold value, the oscillated light beam may be modulated and the oscillation frequency can also be controlled.

Even in this embodiment, the control unit 45 may be configured so that the power of the oscillated light beam emitted from the self-excited oscillation semiconductor laser 1 is controlled using the value of the reverse bias voltage during the oscillation period (see FIG. 4).

The signal loaded on the oscillated light beam from the self-excited oscillation semiconductor laser 1 is not limited to the recording signal, but may be any signal. That is, even in this embodiment, by providing a signal generation unit generating any given signal instead of the recording signal generation unit 39, the optical oscillation unit 110 can be configured as an optical oscillation device that outputs the oscillated light beam on which the any given signal is loaded.

Here, the same operations and advantages can be obtained even when a bi-sectional type self-excited oscillation semiconductor laser including one gain section is used as the self-excited oscillation semiconductor laser 1.

The optical oscillation device and the recording apparatus according to the embodiments of the present application have been described above. The present application is not limited to the above-described embodiments, but may, of course, include various embodiments without departing from the technical spirit and essence within the scope of the claims.

It should be understood by those skilled in the art that various modifications, combinations, sub-combinations and alterations may occur depending on design requirements and other factors insofar as they are within the scope of the appended claims or the equivalents thereof.

The present application may also be configured as below.

(1) A recording apparatus comprising:

a self-excited oscillation semiconductor laser that has a double quantum well separate confinement heterostructure and includes a saturable absorber section to which a negative bias voltage is applied and a gain section into which a gain current is injected;

an optical separation unit that separates an oscillated light beam from the self-excited oscillation semiconductor laser into two oscillated light beams;

an objective lens that condenses one of the separated oscillated light beams on an optical recording medium;

a light reception element that receives the other of the oscillated light beams separated by the optical separation unit;

a pulse detection unit that detects a pulse of the oscillated light beam received by the light reception element;

a reference signal generation unit that generates a master clock signal;

a phase comparison unit that calculates a phase difference between the master clock signal and the pulse;

a recording signal generation unit that generates a recording signal using a negative voltage at a timing of the master clock signal and applies the recording signal as the negative bias voltage to the saturable absorber unit of the self-excited oscillation semiconductor laser; and

a control unit that controls an oscillation frequency of the self-excited oscillation semiconductor laser by changing the gain current to be injected into the gain section of the self-excited oscillation semiconductor laser or the negative bias voltage to be applied to the saturable absorber unit based on the phase difference.

(2) The recording apparatus according to (1), wherein the control unit controls the negative bias voltage during an oscillation period of the self-excited oscillation semiconductor laser.

(3) The recording apparatus according to (2), wherein the negative bias voltage during the oscillation period is a constant direct current voltage.

(4) The recording apparatus according to (3), wherein the control unit controls the gain current during an oscillation period of the self-excited oscillation semiconductor laser.

(5) The recording apparatus according to (4), wherein the gain current during the oscillation period is a constant direct current.

(6) The recording apparatus according to (3) or (5), wherein the control unit controls power of the oscillated light beam by controlling the gain current or the negative bias voltage during the oscillation period.

(7) The recording apparatus according to any one of (1) to (6), wherein the self-excited oscillation semiconductor laser includes a GaInN guide layer, a p-type AlGaN barrier layer, a p-type GaN/AlGaN superlattice first-clad layer, and a p-type GaN/AlGaN superlattice second-clad layer that are sequentially formed on one surface of an active layer.

(8) The recording apparatus according to any one of (1) to (7), wherein the self-excited oscillation semiconductor laser includes an n-type GaN guide layer, an n-type AlGaN clad layer, and an n-type GaN layer that are sequentially formed on the other surface of the active layer.

(9) An optical oscillation device comprising:
a self-excited oscillation semiconductor laser that has a double quantum well separate confinement heterostructure and includes a saturable absorber section to which a negative bias voltage is applied and a gain section into which a gain current is injected;
an optical separation unit that separates an oscillated light beam from the self-excited oscillation semiconductor laser;
a light reception element that receives one of the oscillated light beams separated by the optical separation unit;
a pulse detection unit that detects a pulse of the oscillated light beam received by the light reception element;
a reference signal generation unit that generates a master clock signal;
a phase comparison unit that calculates a phase difference between the master clock signal and the pulse;
a signal generation unit that generates a predetermined signal using a negative voltage at a timing of the master clock signal and applies the predetermined signal as the negative bias voltage to the saturable absorber unit of the self-excited oscillation semiconductor laser; and
a control unit that controls the gain current to be injected into the gain section of the self-excited oscillation semiconductor laser or the negative bias voltage to be applied to the saturable absorber unit based on the phase difference.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A recording apparatus comprising:
a self-excited oscillation semiconductor laser that has a double quantum well separate confinement heterostructure and includes a saturable absorber section to which a negative bias voltage is applied and a gain section into which a gain current is injected;
an optical separation unit that separates an oscillated light beam from the self-excited oscillation semiconductor laser into two oscillated light beams;
an objective lens that condenses one of the separated oscillated light beams on an optical recording medium;
a light reception element that receives the other of the oscillated light beams separated by the optical separation unit;
a pulse detection unit that detects a pulse of the oscillated light beam received by the light reception element;
a reference signal generation unit that generates a master clock signal;
a phase comparison unit that calculates a phase difference between the master clock signal and the pulse;
a recording signal generation unit that generates a recording signal using a negative voltage at a timing of the master clock signal and applies the recording signal as the negative bias voltage to the saturable absorber unit of the self-excited oscillation semiconductor laser; and
a control unit that controls an oscillation frequency of the self-excited oscillation semiconductor laser by changing the gain current to be injected into the gain section of the self-excited oscillation semiconductor laser or the negative bias voltage to be applied to the saturable absorber unit based on the phase difference.

2. The recording apparatus according to claim 1, wherein the control unit controls the negative bias voltage during an oscillation period of the self-excited oscillation semiconductor laser.

3. The recording apparatus according to claim 2, wherein the negative bias voltage during the oscillation period is a constant direct current voltage.

4. The recording apparatus according to claim 1, wherein the control unit controls the gain current during an oscillation period of the self-excited oscillation semiconductor laser.

5. The recording apparatus according to claim 4, wherein the gain current during the oscillation period is a constant direct current.

6. The recording apparatus according to claim 3, wherein the control unit controls power of the oscillated light beam by controlling the gain current or the negative bias voltage during the oscillation period.

7. The recording apparatus according to claim 6, wherein the self-excited oscillation semiconductor laser includes a GaInN guide layer, a p-type AlGaN barrier layer, a p-type GaN/AlGaN superlattice first-clad layer, and a p-type GaN/AlGaN superlattice second-clad layer that are sequentially formed on one surface of an active layer.

8. The recording apparatus according to claim 7, wherein the self-excited oscillation semiconductor laser includes an n-type GaN guide layer, an n-type AlGaN clad layer, and an n-type GaN layer that are sequentially formed on the other surface of the active layer.

9. An optical oscillation device comprising:
a self-excited oscillation semiconductor laser that has a double quantum well separate confinement heterostructure and includes a saturable absorber section to which a negative bias voltage is applied and a gain section into which a gain current is injected;
an optical separation unit that separates an oscillated light beam from the self-excited oscillation semiconductor laser;
a light reception element that receives one of the oscillated light beams separated by the optical separation unit;
a pulse detection unit that detects a pulse of the oscillated light beam received by the light reception element;
a reference signal generation unit that generates a master clock signal;
a phase comparison unit that calculates a phase difference between the master clock signal and the pulse;
a signal generation unit that generates a predetermined signal using a negative voltage at a timing of the master clock signal and applies the predetermined signal as the negative bias voltage to the saturable absorber unit of the self-excited oscillation semiconductor laser; and
a control unit that controls the gain current to be injected into the gain section of the self-excited oscillation semiconductor laser or the negative bias voltage to be applied to the saturable absorber unit based on the phase difference.
